(19) United States
(12) Patent Application Publication
(10) Pub. No.: US 2024/0071818 A1
(43) Pub. Date: Feb. 29, 2024

(54) SEMICONDUCTOR DEVICE AND METHOD OF FABRICATING THE SAME

(71) Applicant: UNITED MICROELECTRONICS CORP., Hsin-Chu City (TW)

(72) Inventors: I-Wei Chi, Kaohsiung City (TW); Te-Chang Hsu, Tainan City (TW); Yao-Jhan Wang, Tainan City (TW); Meng-Yun Wu, Tainan City (TW); Chun-Jen Huang, Tainan City (TW)

(73) Assignee: UNITED MICROELECTRONICS CORP., Hsin-Chu City (TW)

(21) Appl. No.: 17/950,120

(22) Filed: Sep. 22, 2022

(30) Foreign Application Priority Data
Aug. 23, 2022 (TW) 111131624

(51) Int. Cl. H01L 21/768; H01L 21/02; H01L 29/66

(52) U.S. Cl. CPC H01L 21/76829; H01L 21/02041; H01L 21/02293; H01L 21/02529; H01L 21/02532; H01L 29/66795

(57) ABSTRACT

A semiconductor device and method of fabricating the same include a substrate, a first epitaxial layer, a first protection layer, and a contact etching stop layer. The substrate includes a PMOS transistor region, and the first epitaxial layer is disposed on the substrate, within the PMOS transistor region. The first protection layer is disposed on the first epitaxial layer, covering surfaces of the first epitaxial layer. The contact etching stop layer is disposed on the first protection layer and the substrate, wherein a portion of the first protection layer is exposed from the contact etching stop layer.

### BACKGROUND OF THE INVENTION

### 1. Field of the Invention

The present disclosure relates to a semiconductor device and a method of fabricating the same, and more particularly, to a semiconductor device having an epitaxial layer and a method of fabricating the same.

### 2. Description of the Prior Art

With the development of integrated circuits, metal-oxide-semiconductor (MOS) transistors with low power consumption and high integration have been widely used in semiconductor manufacturing. Generally, a MOS transistor includes a gate and two doped regions on both two sides, which are used as a source and a drain, respectively. In some situation, in order to increase the carrier mobility of MOS transistor, a compressive stress or a tensile stress may be optionally applied to the gate channel. For example, in conventional arts, if a compressive stress is needed to be applied, a selective epitaxial growth (SEG) process is performed to form an epitaxial structure with the same lattice arrangement as that of the substrate, such as including a silicon germanium (SiGe) epitaxial layer. Since the lattice constant of the SiGe layer is larger than the lattice constant of the substrate, accordingly, the compressive stress is then formed and applied to the channel region of a P-type MOS (PMOS) transistor, thereby increasing the carrier mobility in the channel region, as well as increasing the efficiency of the PMOS transistor. On the other hand, if a tensile stress is needed to be applied, a silicon carbide (SiC) epitaxial layer may be optionally formed in the substrate of a N-type MOS (NMOS) transistor, to apply the tensile stress to the channel region of the NMOS transistor.

While the foregoing method can improve the carrier mobility in the channel region, said method also has led to the difficulty of the overall fabrication process and the process control, especially under the trend of miniaturization of semiconductor device dimensions. For example, conventional arts usually define a recess region in the substrate, and further form the epitaxial layer in the recess region. However, when the semiconductor device is increasingly miniaturized, it can fail to precisely define the forming position of the recess region. Thus, it is easy to cause some drawbacks, such as damages to the light doped drain (LDD) region leading to short channel effect, resulting in increased leakage current, such that, the quality, and the efficiency of the components will be dramatically affected. Hence, there is a need of proving a novel fabrication method of a semiconductor structure, to obtain more reliable semiconductor device.

### SUMMARY OF THE INVENTION

The present disclosure is to provide a semiconductor device and a fabricating method thereof, where a protection layer with an oxide material is additionally disposed on an epitaxial layer, to improve the leakage current issues, so as to gain a more reliable semiconductor device.

To achieve the aforementioned objects, the present disclosure provides a semiconductor device including a substrate, a first epitaxial layer, a first protection layer, and a contact etching stop layer. The substrate includes a P-type metal-oxide-semiconductor (PMOS) transistor region, and the first epitaxial layer is disposed on the substrate, within the PMOS transistor region. The first protection layer is disposed on the first epitaxial layer, covering surfaces of the first epitaxial layer. The contact etching stop layer (CESL) is disposed on the first protection layer and the substrate, wherein a portion of the first protection layer is exposed from the CESL.

To achieve the aforementioned objects, the present disclosure provides a method of fabricating a semiconductor device, including the following steps. Firstly, a substrate is provided and the substrate having a PMOS transistor region and a first epitaxial layer is formed on the substrate, within the PMOS transistor region. Next, a first protection layer is formed on the first epitaxial layer, covering surfaces of the first epitaxial layer. Then, a CESL is formed on the first protection layer and the substrate, wherein a portion of the first protection layer is exposed from the CESL.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 10 illustrate schematic diagrams of a fabricating method of a semiconductor device according to a first embodiment of the present disclosure, in which:

FIG. 1 is a schematic perspective view of a semiconductor device after forming an epitaxial layer;

FIG. 2 is a schematic cross-sectional view of a semiconductor device taken along cross lines A-A′, B-B′;

FIG. 3 is a schematic cross-sectional view of a semiconductor device after partially removing fin shaped structures;

FIG. 4 is a schematic cross-sectional view of a semiconductor device after forming another epitaxial layer;

FIG. 5 is a schematic cross-sectional view of a semiconductor device after performing an oxidation treatment;

FIG. 6 is a schematic cross-sectional view of a semiconductor device after performing a source/drain implanting process;

FIG. 7 is a schematic cross-sectional view of a semiconductor device after performing another source/drain implanting process;

FIG. 8 is a schematic cross-sectional view of a semiconductor device after performing a cleaning process;

FIG. 9 is a schematic cross-sectional view of a semiconductor device after performing another oxidation treatment; and

FIG. 10 is a schematic cross-sectional view of a semiconductor device after forming a contact etching stop layer.

FIG. 11 to FIG. 12 illustrate schematic diagrams of a fabricating method of a semiconductor device according to a second embodiment of the present disclosure, in which:

FIG. 11 is a schematic cross-sectional view of a semiconductor device after performing a cleaning process; and

FIG. 12 is a schematic cross-sectional view of a semiconductor device after forming a contact etching stop layer.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

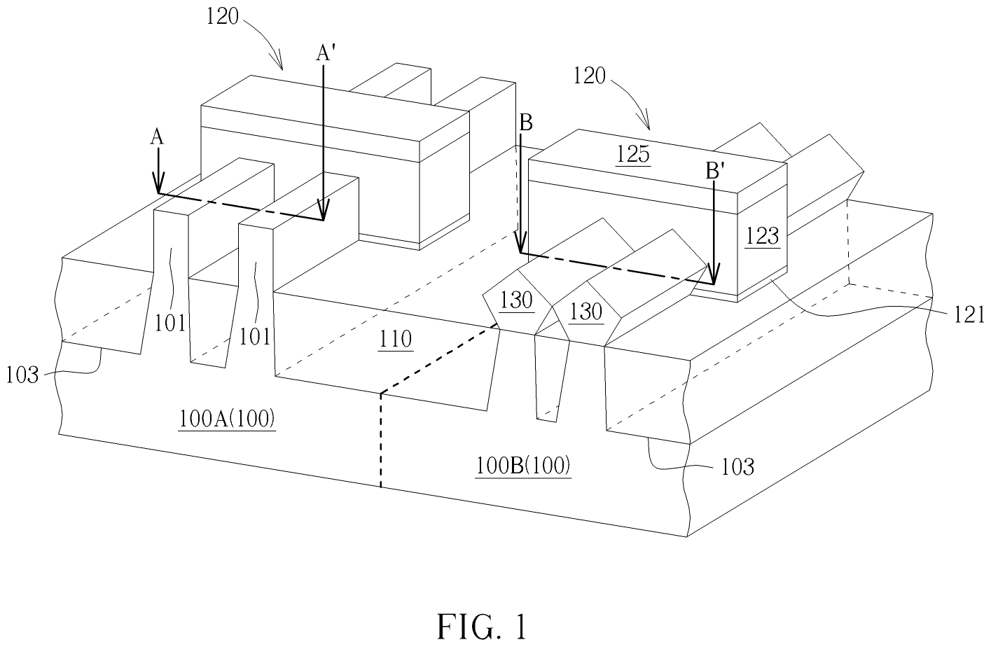

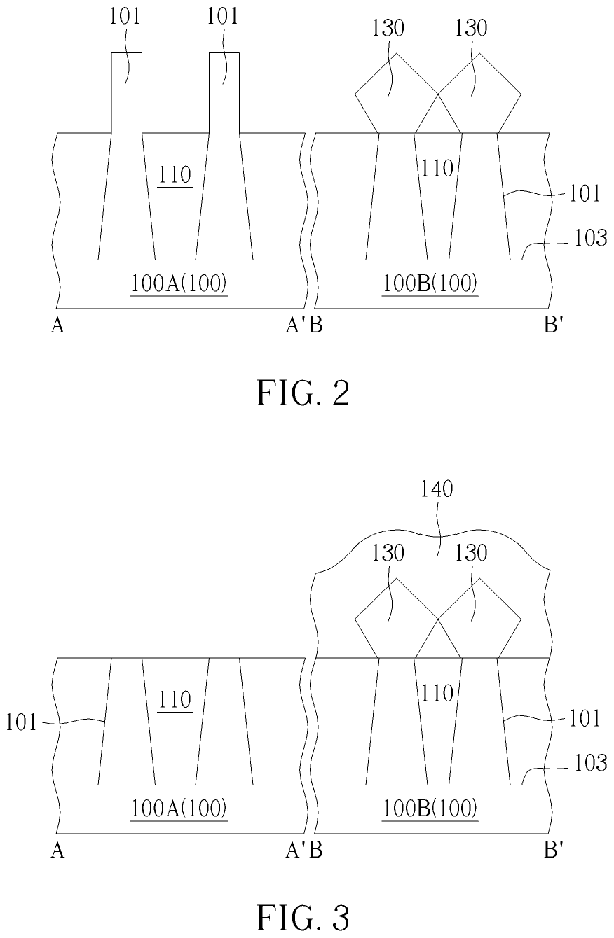

Please refer to FIG. 1 to FIG. 10, which respectively illustrate a schematic diagram of a fabricating method of a semiconductor device according to the first embodiment of the present disclosure, wherein FIG. 1 is a schematic perspective view of a semiconductor device 300 at a primary fabricating stage, and FIG. 2 to FIG. 10 are schematic cross-sectional views of a semiconductor device 300 during various fabricating stages. Firstly, as shown in FIG. 1 and FIG. 2, a device 100 is provided, for example a silicon substrate, an epitaxial silicon substrate, a silicon germanium substrate, a silicon carbide substrate, or a silicon-on-insulator (SOI) substrate. Due to practical requirements, the substrate 100 may further include transistor regions with the same or different conductivity types, such as P-type metal-oxide-semiconductor (PMOS) transistor regions and/or N-type metal-oxide-semiconductor (NMOS) transistor regions, for forming metal-oxide-semiconductor transistors with various functions in subsequent processes, but not limited thereto.

In the present embodiment, a plurality of fin shaped structures 101 and a shallow trench isolation 110 are further formed in the substrate 100, and at least one gate structure 120 is formed on the substrate 100. In one embodiment, the formation of the fin shaped structure 101 and the shallow trench isolation 110 includes but is not limited to the following steps. Firstly, a patterned mask (not shown in the drawings) is formed on the substrate 100, and an etching process is performed to transfer the patterns of the patterned mask into the substrate 100, to form a plurality of trenches (not shown in the drawings), also to form the fin shaped structures 101 which are protruded from a plane 103 of the substrate 100 at the same time. Subsequently, after removing the patterned mask, an insulating layer (not shown in the drawings) is filled in the trenches, followed by partially removing the insulating layer, to expose a portion of the fin shaped structure 101, and to form the shallow trench isolation 110. It is noted that, in other embodiments, if the transistor to be manufactured subsequently is a planar transistor, the formation of the fin shaped structure may be omitted, and the gate structure may be directly formed on a planar substrate (not shown in the drawings).

Precisely speaking, two gate structures 120 which are disposed in a side by side manner are formed in the present embodiment, to respectively cross over the fin shaped structures 101 within a PMOS transistor region 100A and the fin shaped structures 101 within a NMOS transistor region 100B. The gate structure 120 at least includes a gate dielectric layer 121, a gate layer 123, and a capping layer 125 stacked from bottom to top. In one embodiment, the gate dielectric layer 121 for example includes a dielectric material like silicon oxide, the gate layer 123 for example includes a semiconductor material like polysilicon or amorphous silicon, and the capping layer 125 for example includes silicon nitride, silicon carbide (SiC), silicon carbinitride (SiCN), or a combination thereof, but is not limited thereto. In the present embodiment, the formation of the gate structures 120 for example includes but is not limited to the following steps. Firstly, stacked material layers including a dielectric material layer (not shown in the drawings), a gate material layer (not shown in the drawings), and a capping material layer (not shown in the drawings) are conformally formed on the substrate 100, and the stacked material layers are patterned to form the gate structures 120. Following these, a spacer (not shown in the drawings) may be further formed on sidewalls of the gate structures 120. People in the art should fully understand that the gate structures 120 of the present disclosure may further form into a metal gate (not shown in the drawings) by performing a gate-last process and a high-k last process in the subsequent processes, but not limited thereto. In another embodiment, a metal gate structure (not shown in the drawings) may be directly formed on the substrate, and the metal gate structure at least includes a word function metal layer and a metal gate.

Further in view of FIG. 1 and FIG. 2, an epitaxial layer 130 is formed in the NMOS transistor region 100B, and which for example includes a pentagon-like cross-sectional shape, or other cross-sectional shapes like a circular shape, a hexagon (also known as sigma Z) shape or an octagon shape, but it is not limited thereto. In the present embodiment, the formation of the epitaxial layer 130 for example includes but is not limited to the following steps. Firstly, a mask layer (not shown in the drawings) is formed to cover the PMOS transistor region 100A, an etching process is performed to remove a portion of the fin shaped structures 101 disposed at two sides of the gate structures 120, and a selective epitaxial growth (SEG) process is next performed to form the epitaxial layer 130 on the removed portion of the fin shaped structures 101, with the epitaxial layer 130 being partially protruded from the top surface of the shallow trench isolation 110. Preferably, the epitaxial layers 130 formed on the fin shaped structures 101 which are adjacent to each other may be partially merged to become integration, as shown in FIG. 2, but is not limited thereto. Then, the mask layer is removed. It is noted that, the material of the epitaxial layer 130 may be adjusted according to the type of the MOS transistor, for example including SiC, silicon carbide phosphide (SiCP) or silicon phosphide (SiP), and the epitaxial layer 130 may be formed by the SEG process through a single or a multiple layer approach, and the heterogeneous atoms (such as phosphorus or carbon atoms) may also be altered in a gradual arrangement, preferably with the surface of the epitaxial layer 130 having a relative lighter concentration or no carbon atoms or phosphorus atoms at all, but not limited thereto.

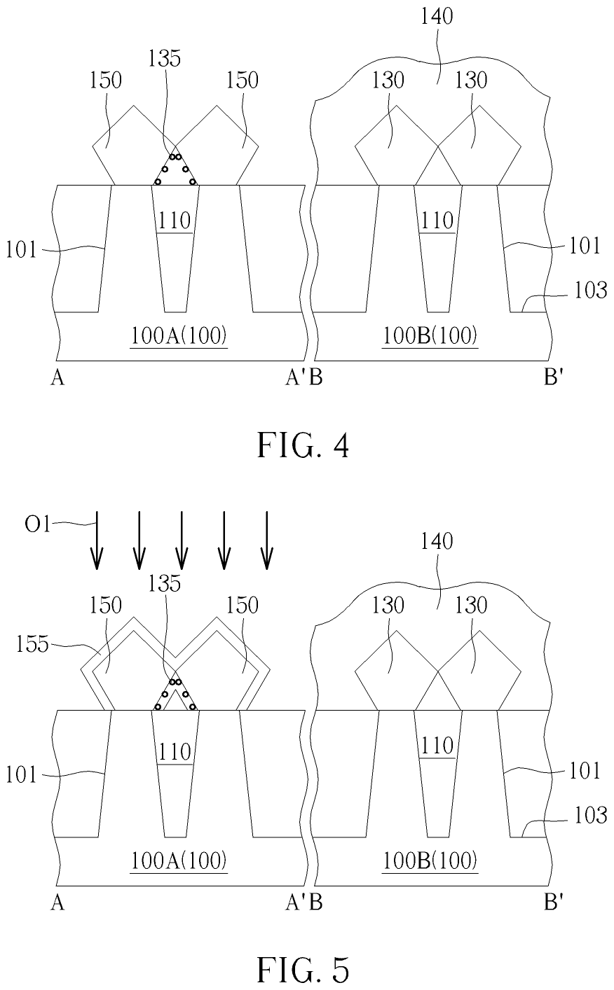

As shown in FIG. 3 to FIG. 4, an epitaxial layer 150 is next formed in the PMOS transistor region 100A, and which may also include a pentagon-like cross-sectional shape, or other cross-sectional shapes like a circular shape, a hexagon shape or an octagon shape, but is not limited thereto. Firstly, as shown in FIG. 3, a mask layer 140 (for example including a material like silicon nitride) is formed in the NMOS transistor region 100B, to entirely and conformally cover the epitaxial layer 130 and the shallow trench isolation 110, and then, an etching process such as a dry etching process is performed to partially remove the fin shaped structures 101 at two sides of the gate structures 120, for example removing the portion of the fin shaped structure 101 which is protruded from the shallow trench isolation 110. Then, as shown in FIG. 4, a SEG process is performed to form the epitaxial layer 150 on the portion of the fin shaped structure 101, with the epitaxial layer 150 being partially protruded from the surface of the shallow trench isolation 110. Preferably, the epitaxial layers 150 formed on the fin shaped structures 101 which are adjacent to each other may be partially merged to become integration, but is not limited thereto. It is noted that, the material of the epitaxial layer 150 may be adjusted according to the type of the MOS transistor, for example including SiGe, silicon-germanium-boron (SiGeB) or silicon-germanium-tin silicide (SiGeSn). Likewise, the epitaxial layer 150 may also be formed by the SEG process through a single or a multiple layer approach, and the heterogeneous atoms (such as germanium atoms) may also be altered in a gradual arrangement, preferably with the surface of the epitaxial layer 150 having a relative lighter concentration or no germanium atoms at all, but not limited thereto. Furthermore, it is also noted that, while performing the SEG process, phosphorus residues 135 left by the previous formation of the epitaxial layer 130 may be attached to the epitaxial layer 150, especially at the gap between the adjacent epitaxial layers 150, as shown in FIG. 4.

As shown in FIG. 5, after forming the epitaxial layer 150, a first oxidation treatment O1 for example a thermal oxidation process is performed through the mask layer 140, to form an oxide layer 155 on the epitaxial layer 150, followed by completely removing the mask layer 140. The oxide layer 155 for example includes an oxide material of silicon, germanium (Ge), boron (B), or tin (Sn), but is not limited thereto. It is noted that, while forming the oxide layer 155, the phosphorus residues 135 originally attached to the epitaxial layer 150 may be embedded inside the oxide layer 150. With such arrangement, the oxide layer 155 may further include the phosphorus residues 135 remained therein, thereby avoiding the issues that the phosphorus residues 135 attached to the epitaxial layer 150 to generate an N-type junction to lead to leakage currents.

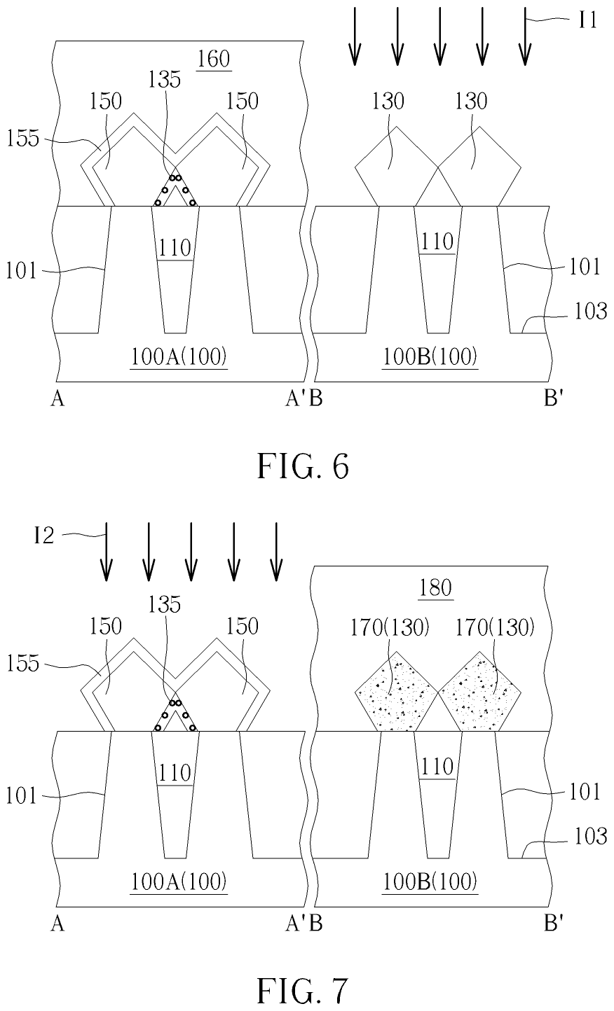

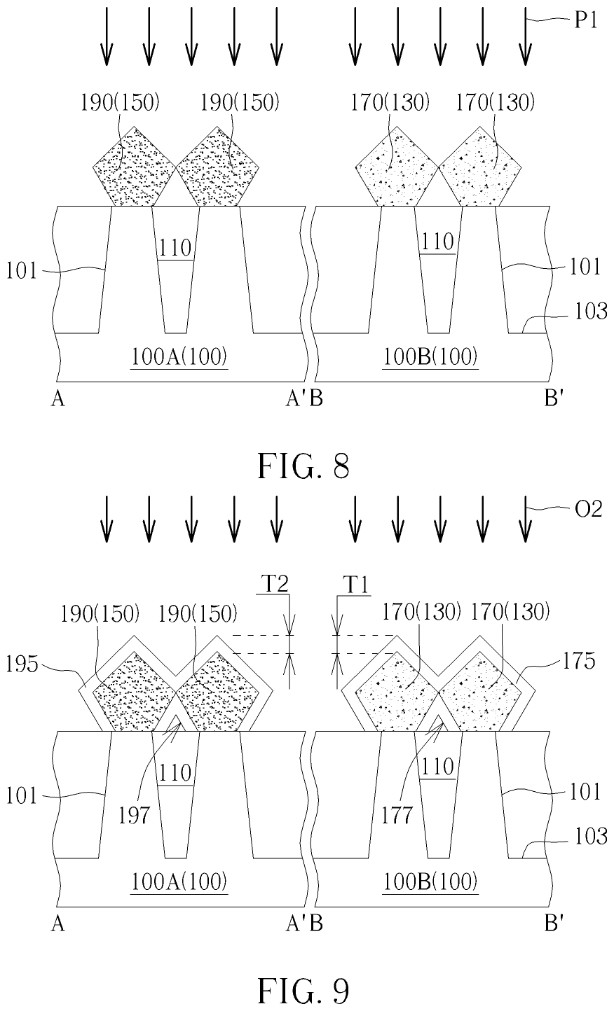

As shown in FIG. 6 to FIG. 8, ion implanting processes of source/drain doped regions are performed, to form source/drains in at least a portion of the epitaxial layers 130 and the epitaxial layers 150. Precisely speaking, as shown in FIG. 6, a mask layer 160 is formed in the PMOS transistor region 100A, to cover the epitaxial layers 150, and an implanting process I1 is performed on the epitaxial layers 130, to dope a N-type dopant in a portion or all of the epitaxial layers 130, and to form source/drains 170 as shown in FIG. 7. Then, the mask layer 160 is completely removed. Following these, as shown in FIG. 7, a mask layer 180 is formed in the NMOS transistor region 100B, to cover the epitaxial layers 130 (namely, the source/drains 170), and another implanting process 12 is performed on the epitaxial layers 150 by using the oxide layer 155 as a buffering layer, to dope a P-type dopant in a portion or all of the epitaxial layers 150, and to form source/drains 190 as shown in FIG. 8. The mask layer 180 is completely removed. In one embodiment, the formation of the source/drains 170 and/or the source/drains 190 may also be in-situ formed while forming the epitaxial layer 130s and/or the epitaxial layers 150. For example, a SiC epitaxial layer, a SiCP epitaxial layer or a SiP epitaxial layer may be doped in-situ with N type dopants to form a N⁺ epitaxial structure thereby, or a SiGe epitaxial layer, a SiGeB epitaxial layer or a SiGeSn epitaxial layer may be doped in-situ with P type dopants to form a P⁺ epitaxial structure thereby. Thus, the following ion implantation process for forming the source/drains of the PMOS/NMOS transistors may be omitted.

As shown in FIG. 8, after removing the mask layer 180, a cleaning process P1 is performed with dilute hydrogen fluoride (DHF), to remove the residues left by removing the mask layer 160 and/or the mask layer 180. It is noted that, the oxide layer 155 disposed on the epitaxial layer 150 may also be removed during the cleaning process P1, with the oxide layer 155, as well as the phosphorus residues 135 embedded therein being both removed completely as shown in FIG. 8, and the epitaxial layers 150 (namely, the source/drains 190) disposed underneath is exposed.

As shown in FIG. 9, after performing the cleaning process P1, a second oxidation treatment O2 such as a thermal oxidation process is performed, to form an oxide layer on surface of the epitaxial layers 130 (namely, the source/drains 170) and surfaces of the epitaxial layers 150 (namely, the source/drains 190), and there is no phosphorus residue in the oxide layer formed by the second oxidation treatment O2. Accordingly, the oxide layer may enable to serve as a protection layer 175 of the epitaxial layers 130 (namely, the source/drains 170) and a protection layer 195 of the epitaxial layers 150 (namely, the source/drains 190). It is noted that, the protection layer 175 and the protection layer 195 are uniformly formed on all exposing surfaces of the epitaxial layers 130 (namely, the source/drains 170) and the epitaxial layers 150 (namely, the source/drains 190), and a portion of the protection layer 177 and a portion of the protection layer 197 may be sandwiched between the adjacent epitaxial layers 130 and/or the adjacent epitaxial layers 150. In one embodiment, the protection layer 175 and the protection layer 195 for example both include an oxide material, wherein the protection layer 175 for example an oxide material of silicon, carbon (c), or phosphorus (p), and the protection layer 195 for example includes an oxide material of silicon, germanium, boron or tin, but is not limited thereto. In addition, the protection layer 175 and the protection layer 195 may respectively have uniform thicknesses T1 and T2, and preferably, the thickness T1 of the epitaxial layers 130 (namely, the source/drains 170) may be substantially the same as the thickness T2 of the epitaxial layers 150 (namely, the source/drains 190).

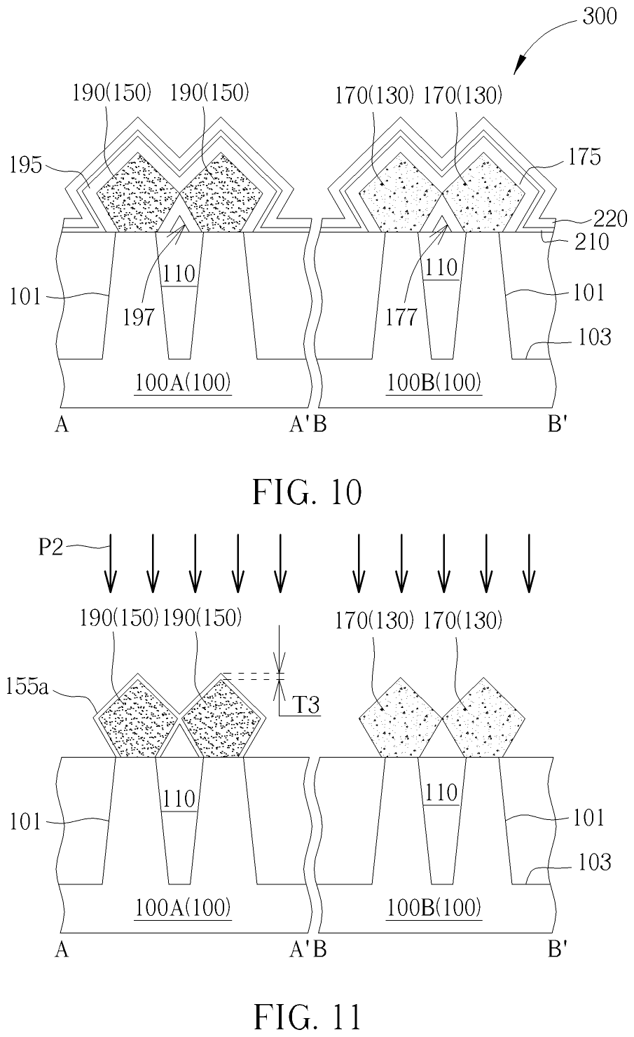

After that, as shown in FIG. 10, a contact etching stop layer (CESL) 220 is formed on the substrate 100, to cover the gate structures 120 (not shown in FIG. 10), the protection layer 175, the protection layer 195, the epitaxial layers 130 namely, the source/drains 170), and the epitaxial layers 150 (namely, the source/drains 190) at the same time, so as to apply the required compressive stress or the tensile stress to the gate structures 120 or the metal structures formed subsequently. It is noted that, since the adjacent epitaxial layers 130 and/or the adjacent epitaxial layers 150 are partially merged with each other, the portion of the protection layer 177 and the portion of the protection layer 197 may not be covered by the CESL 220, to be exposed from the CESL 220 thereby.

In addition, it is also noted that, in one embodiment, a deposition process may be additionally performed before forming the CESL 220, to form a stress buffering layer 210 on the substrate 100, and the stress buffering layer 210 for example includes an oxide material like silicon oxide, preferably, including a material the same as that of the protection layer 195 (for example silicon dioxide), but not limited thereto. The stress buffering layer 210 also covers the gate structures 120 (not shown in FIG. 10), the protection layer 175, the protection layer 195, the epitaxial layers 130 (namely, the source/drains 170), and the epitaxial layers 150 (namely, the source/drains 190) at the same time, with the portion of the protection layer 177 and the portion of the protection layer 197 being not covered by the stress buffering layer 210 and exposed from the stress buffering layer 210. Accordingly, the CESL 220 formed next will completely cover on the stress buffering layer 210, as shown in FIG. 10.

Through the aforementioned steps, the fabricating method of semiconductor device 300 according to the first embodiment of the present disclosure is accomplished. According to the fabricating method of the present embodiment, the oxide layer 155 is additionally formed on the epitaxial layers 150 before performing the cleaning process P1, with the oxide layer 155 being coated on the phosphorus residues 135 remained on the epitaxial layers 150, so as to avoid the issues that the phosphorus residues 135 attached to the epitaxial layer 150 to generate an N-type junction to lead to leakage currents. Following these, the oxide layer 155, as well as the phosphorus residues 135 embedded inside the oxide layer 155, are both removed completely during the cleaning process P1, and the protection layers 175, 195 are then formed on the epitaxial layers 130 (namely, the source/drains 170) and the epitaxial layers 150 (namely, the source/drains 190) after performing the cleaning process P1, to maintain the integrity of the epitaxial layers 130 (namely, the source/drains 170) and the epitaxial layers 150 (namely, the source/drains 190). In this way, the semiconductor device 300 of the present embodiment is capable of improving the leakage current issues caused by the excessive spacing between the fin shaped structures 101, the attached phosphorus residues 135, and/or the oversized or undersized epitaxial structures, thereby effectively enhancing the device performance.

People skilled in the art should fully understand that the semiconductor device and the fabricating method thereof are not limited to be what is shown in the aforementioned embodiments, and which may further include other examples based on practical product requirements. The following description will detail other different embodiments or variant embodiments of the semiconductor device and the fabricating method thereof of the present disclosure. To simplify the description, the following description will detail the dissimilarities among the different embodiments and the identical features will not be redundantly described. In order to compare the differences between the embodiments easily, the identical components in each of the following embodiments are marked with identical symbols.

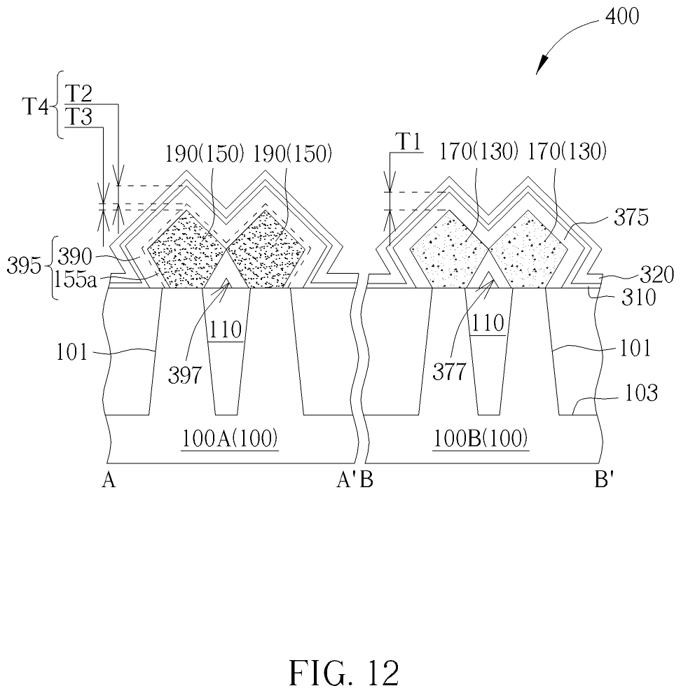

Please refer to FIG. 11 to FIG. 12, which are schematic diagrams illustrating a fabricating method of a semiconductor device 400 according to the second embodiment of the present disclosure. The formal steps in the present embodiment are similar to those in the first embodiment, as shown in FIG. 1 to FIG. 7, and which may not be redundantly described herein. The difference between the present embodiment and the aforementioned first embodiment is in that, a cleaning process P2 of the present embodiment only partially remove the oxide layer 155.

Precisely speaking, as shown in FIG. 11, after removing the mask layer 180 as shown in FIG. 7, the cleaning process P2 is performed in which the diluted hydrogen fluoride is used to remove the residue left by removing the mask layer 160 as shown in FIG. 6 and/or the mask layer 180 as shown in FIG. 7. Accordingly, the oxide layer 155 disposed on the epitaxial layer 150 is partially removed, and the phosphorus residues 135 embedded in the oxide layer 155 is completely remove, during the cleaning process P2. In this way, after performing the cleaning process P2, the entire surfaces of the epitaxial layers 150 (namely, the source/drains 190) are still covered by a remained oxide layer 155a, and the remained oxide layer 155a has a relative smaller thickness T3 in comparison with that of the oxide layer 155, as shown in FIG. 11.

After that, as shown in FIG. 12, after the cleaning process P2, a second oxidation treatment (as shown in FIG. 9 of the aforementioned first embodiment) such as a thermal oxidation process is performed, to form an oxide layer on surface of the epitaxial layers 130 (namely, the source/drains 170) and surfaces of the remained oxide layer 155a at the same time, and a stress buffering layer 310 and a CESL 320 are next formed on the substrate 100. It is noted that, in the present embodiment, the oxide layer formed on the epitaxial layers 130 (namely, the source/drains 170) may therefore serve as a protection layer 375 of the epitaxial layers 130 (namely, the source/drains 170), the protection layer 375 includes a monolayer structure and an uniform thickness T1. On the other hand, the remained oxide layer 155a and an oxide layer 390 stacked sequentially on the epitaxial layers 150 (namely, the source/drains 190) may together serve as a protection layer 395 of the epitaxial layers 150 (namely, the source/drains 190), and the protection layer 395 includes a bilayer structure. The remained oxide layer 155a and the oxide layer 390 respectively include the uniform thicknesses T3 and T2, and the thickness T2 of the oxide layer 390 is greater than the thickness T3 of the oxide layer 133, so that, an entire thickness T4 of the protection layer 395 is obviously greater than the thickness T1 of the protection layer 375. Also, a portion of the protection layer 377 and a portion of the protection layer 397 are exposed from the CESL 320, as shown in FIG. 12. In the present embodiment, the protection layer 375 for example includes an oxide material of silicon, carbon, or phosphors, and the protection layer 395 (including the remained oxide layer 155a and the oxide layer 390) for example includes an oxide material of silicon, germanium, boron or tin, but not limited thereto. Preferably, the stress buffering layer 210 includes the same material as that of the protection layer 395 (including the remained oxide layer 155a and the oxide layer 390) or the protection layer 375, such as silicon dioxide, but not limited thereto.

Through the aforementioned steps, the fabricating method of semiconductor device 400 according to the second embodiment of the present disclosure is accomplished. According to the fabricating method of the present embodiment, the oxide layer 155 additionally formed on the epitaxial layer 150 is partially removed in the cleaning process P2, and another oxide layer is further formed through the second oxidation treatment, after performing the cleaning process P2. Accordingly, the protection layer 375 covered on the epitaxial layers 130 (namely, the source/drains 170) only includes a monolayer structure, and which includes the oxide layer only formed in the second oxidation treatment. On the other hand, the protection layer 395 covered on the epitaxial layers 150 (namely, the source/drains 190) includes a bilayer structure, and the bilayer structure includes the remained oxide layer 155a and the oxide layer 390 which is formed in the second oxidation treatment stacked sequentially on the epitaxial layers 150 (namely, the source/drains 190). In this way, the protection layers 375, 395 also enable to maintain the integrity of the epitaxial layers 130 (namely, the source/drains 170) and the epitaxial layers 150 (namely, the source/drains 190). Then, the semiconductor device 400 of the present embodiment is also capable of improving the leakage current issues caused by the excessive spacing between the fin shaped structures 101, the attached phosphorus residues 135, and/or the oversized or undersized epitaxial structures, thereby effectively enhancing the device performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, having a P-type metal-oxide-semiconductor (PMOS) transistor region;
a first epitaxial layer, disposed on the substrate, within the PMOS transistor region;
a first protection layer, disposed on the first epitaxial layer, covering surfaces of the first epitaxial layer; and
a contact etching stop layer (CESL), disposed on the first protection layer and the substrate, wherein a portion of the first protection layer is exposed from the CESL.

2. The semiconductor device according to claim 1, wherein the first protection layer comprises a bilayer structure having a first oxide layer and a second oxide layer stacked sequentially on the first epitaxial layer.

3. The semiconductor device according to claim 2, wherein a thickness of the second oxide layer is greater than that of the first oxide layer.

4. The semiconductor device according to claim 1, further comprising a stress buffering layer disposed between the first protection layer and the CESL, wherein the stress buffering layer and the first protection layer comprise a same material.

5. The semiconductor device according to claim 1, further comprising:
a second epitaxial layer disposed on the substrate, within a N-type metal-oxide-semiconductor (NMOS) transistor region of the substrate; and
a second protection layer disposed on the second epitaxial layer, covering surfaces of the second epitaxial layer.

6. The semiconductor device according to claim 5, wherein the first protection layer and the second protection layer comprise a same thickness.

7. The semiconductor device according to claim 5, wherein the first protection layer comprises a bilayer structure and the second protection layer comprises a monolayer structure.

8. The semiconductor device according to claim 5, further comprising:
a plurality of fin shaped structures disposed in the substrate and partially protruded from a plane of the substrate, wherein the first epitaxial layer and the second epitaxial layer are respectively disposed on the fin shaped structures.

9. The semiconductor device according to claim 5, wherein the second epitaxial layer comprises silicon carbide (SiC), silicon carbide phosphide (SiCP) or silicon phosphide (SiP), and the first epitaxial layer comprises silicon germanium (Site), silicon-germanium-boron (SiGeB) or silicon-germanium-tin silicide (SiGeSn).

10. A method of fabricating a semiconductor device, comprising:
providing a substrate having a P-type metal-oxide-semiconductor (PMOS) transistor region;
forming a first epitaxial layer on the substrate, within the PMOS transistor region;
forming a first protection layer on the first epitaxial layer, covering surfaces of the first epitaxial layer; and
forming a contact etching stop layer (CESL) on the first protection layer and the substrate, wherein a portion of the first protection layer is exposed from the CESL.

11. The method of fabricating the semiconductor device according to claim 10, wherein the forming of the first protection layer further comprising:
after forming the first epitaxial layer, performing a first oxidation treatment to form a first oxide layer on the first epitaxial layer;
performing an implanting process on the first epitaxial layer;
performing a cleaning process, to remove the first oxide layer; and
after the cleaning process, performing a second oxidation treatment to form a second oxide layer on the first epitaxial layer.

12. The method of fabricating the semiconductor device according to claim 11, wherein the first oxide layer comprises a phosphorus residue and the second oxide layer does not comprise a phosphorus residue, and the phosphorus residue within the first oxide layer is removed after the cleaning process.

13. The method of fabricating the semiconductor device according to claim 11, wherein the first oxide layer is completely removed while performing the cleaning process, and the first protection layer comprises the second oxide layer.

14. The method of fabricating the semiconductor device according to claim 11, wherein the first oxide layer is partially removed while performing the cleaning process, and the first protection layer comprises a remain portion of the first oxide layer and the second oxide layer stacked sequentially on the first epitaxial layer.

15. The method of fabricating the semiconductor device according to claim 11, further comprising:
forming a second epitaxial layer on the substrate, within a N-type metal-oxide-semiconductor (NMOS) transistor region of the substrate; and
forming a second protection layer on the second epitaxial layer, covering surfaces of the second epitaxial layer.

16. The method of fabricating the semiconductor device according to claim 15, further comprising:
after the cleaning process, performing the second oxidation treatment to form the second oxide layer on the second epitaxial layer, wherein the second protection layer comprises the second oxide layer.

17. The method of fabricating the semiconductor device according to claim 15, further comprising:
forming a plurality of fin shaped structures in the substrate and partially protruded from a plane of the substrate, wherein the first epitaxial layer and the second epitaxial layer are respectively formed on the fin shaped structures.

18. The method of fabricating the semiconductor device according to claim 11, wherein the first oxidation treatment and the second oxidation treatment respectively comprise a thermal oxidation process.

19. The method of fabricating the semiconductor device according to claim 18, further comprising:
after forming the first protection layer, performing a deposition process to form a stress buffering layer on the first protection layer and the substrate; and
forming the CESL on the stress buffering layer.

20. The method of fabricating the semiconductor device according to claim 19, wherein the stress buffering layer and the first protection layer comprise a same material.
